(19) United States
(12) Patent Application Publication
(10) Pub. No.: US 2023/0011839 A1
(43) Pub. Date: Jan. 12, 2023

(54) LIGHT-EMITTING DEVICE

(71) Applicant: SHARP KABUSHIKI KAISHA, Sakai City, Osaka (JP)

(72) Inventor: YOSHIHIRO UETA, Sakai City, Osaka (JP)

(21) Appl. No.: 17/781,882

(22) PCT Filed: Dec. 9, 2019
(86) PCT No.: PCT/JP2019/048127

§ 371 Date: Jun. 2, 2022

(51) Int. Cl. H01L 51/50; H01L 51/52

(52) U.S. Cl. CPC H01L 51/5072; H01L 51/5225; H01L 51/502; H01L 2251/305

(57) ABSTRACT

A light-emitting device includes a light-emitting layer, an electron transport layer provided on the light-emitting layer, and a cathode provided on the electron transport layer. A main component of the cathode is a metal boride. With the above configuration, a work function of the cathode is reduced and electron injection efficiency is improved. As a result, luminous efficiency of the light-emitting device is improved.

### TECHNICAL FIELD

The disclosure relates to a light-emitting device.

### BACKGROUND ART

PTL 1 describes a light-emitting device having a structure in which the periphery of a light-emitting element is surrounded by a partition of a porous structure. PTL 2 describes an organic electroluminescence display device including an inorganic porous film between an organic film and an organic electroluminescence layer outside a display region. PTL 3 describes a manufacturing method for an anti-reflection film used in an optical element of a display device or the like, by using a die having a porous alumina layer.

### CITATION LIST

### Patent Literature

PTL 1: JP 2013-30467 A

PTL 2: JP 2016-115572 A

PTL 3: WO 2011/125486

### SUMMARY

### Technical Problem

A known cathode has a large work function with respect to a light-emitting layer, and thus a barrier with respect to electron injection is large and electron injection efficiency is low. As a result, the luminous efficiency of the light-emitting device is reduced. In particular, in a light-emitting device using a quantum dot layer as a light-emitting layer, the work function of the quantum dot layer becomes smaller as the wavelength of the emitted light becomes shorter in sequence of red, green, and blue, whereby the electron injection becomes difficult.

The disclosure has been contrived to solve the problems described above, and the object of the disclosure is to improve luminous efficiency of a light-emitting device by improving electron injection efficiency from a cathode to a light-emitting layer.

### Solution to Problem

In order to solve the problems described above, a light-emitting device according to an aspect of the disclosure includes a light-emitting layer, an electron transport layer provided on the light-emitting layer, and a cathode provided on the electron transport layer, and a main component of the cathode is a metal boride.

### Advantageous Effects of Disclosure

According to an aspect of the disclosure, because the main component of the cathode is a metal boride, a work function with respect to the light-emitting layer is small, so that the electron injection efficiency is improved. As a result, the luminous efficiency of the light-emitting device may be improved.

### BRIEF DESCRIPTION OF DRAWINGS

FIG. 1 is a schematic cross-sectional view of a light-emitting device according to a first embodiment of the disclosure.

FIG. 2 is an energy band diagram of a light-emitting device according to the first embodiment of the disclosure.

FIG. 3 is a refractive index distribution diagram of a light-emitting device according to the first embodiment of the disclosure.

FIG. 4 is a schematic cross-sectional view of a light-emitting device according to a comparative example.

FIG. 5 is an energy band diagram of a light-emitting device according to the comparative example.

FIG. 6 is a refractive index distribution diagram of a light-emitting device according to the comparative example.

FIG. 7 is a graph comparing electrical characteristics between a light-emitting device according to the first embodiment and a light-emitting device according to the comparative example.

FIG. 8 is a schematic cross-sectional view of a light-emitting device according to a second embodiment of the disclosure.

FIG. 9 is a refractive index distribution diagram of a light-emitting device according to the second embodiment of the disclosure.

FIG. 10 is a schematic cross-sectional view enlarging part of a cathode included in a light-emitting device according to the second embodiment of the disclosure.

FIG. 11A is a diagram describing a step of forming a cathode included in a light-emitting device according to the second embodiment of the disclosure.

FIG. 11B is a diagram describing a step of forming a cathode included in a light-emitting device according to the second embodiment of the disclosure.

FIG. 11C is a diagram describing a step of forming a cathode included in a light-emitting device according to the second embodiment of the disclosure.

FIG. 11D is a diagram describing a step of forming a cathode included in a light-emitting device according to the second embodiment of the disclosure.

FIG. 12 is a schematic cross-sectional view of a modified example of a light-emitting device according to the second embodiment of the disclosure.

### DESCRIPTION OF EMBODIMENTS

### First Embodiment

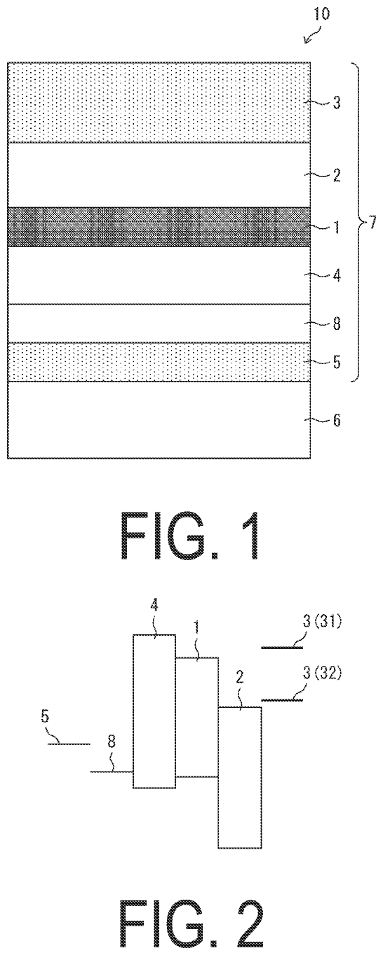

FIG. 1 is a schematic cross-sectional view of a light-emitting device 10 according to the present embodiment. The light-emitting device 10 is used, for example, for display or lighting. The light-emitting device 10 includes a light-emitting layer 1, an electron transport layer 2 provided on the light-emitting layer 1, and a cathode 3 provided on the electron transport layer 2. As illustrated in FIG. 1, the light-emitting device 10 of the present embodiment includes an anode 5 provided on an array substrate 6, where a thin film transistor (TFT) (not illustrated) is formed, and a hole transport layer 4 provided on the anode 5. The light-emitting layer 1 is provided on the hole transport layer 4. In the light-emitting device 10, a layered structure in which each of the layers including the anode 5, a hole injection layer 8, the hole transport layer 4, the light-emitting layer 1, the electron transport layer 2, and the cathode 3 is layered is referred to as a light-emitting element 7. Thus, the light-emitting device 10 includes a pair of electrodes of the anode 5 and cathode 3, and a pair of carrier transport layers of the hole transport layer 4 and the electron transport layer 2. The light-emitting device 10 may further include a pair of carrier injection layers such as the hole injection layer 8, an electron injection layer (not illustrated) and the like.

In the present specification, the “upper side” in the light-emitting device 10 is the cathode 3 side, and the “lower side” therein is the array substrate 6 side. The “upper face” of the cathode 3 is intended to be a face on the opposite side to a face of the cathode 3 on the side in contact with the electron transport layer 2. In the present embodiment, the light-emitting device 10 is a top-emitting type light-emitting device configured to emit light from the upper face of the cathode 3. However, the disclosure is not limited thereto, and a bottom-emitting type light-emitting device configured to emit light from the lower side of the array substrate 6 is also included within the scope of the disclosure.

The array substrate 6 is a substrate where the TFT for driving the anode 5 and the cathode 3 is formed. The material used in the substrate may be a hard material such as glass, or may be a flexible material such as plastic, resin or the like. In a case where a flexible material is used for the array substrate 6, the flexible light-emitting device 10 may be obtained.

The anode 5 injects positive holes into the hole transport layer 4. The anode 5 is provided on the array substrate 6, and is electrically connected to the TFT. The anode 5 contains a conductive material. In the top-emitting type light-emitting device 10, the anode 5 is a reflective electrode, and therefore it is preferable to contain a metal material. The metal material contained in the anode 5 is preferably Al, Cu, Au, Ag, or the like having high reflectivity of visible light. As described below, because a difference in ionization energy between each of the layers from the anode 5 to the light-emitting layer 1 becomes a barrier for the hole transport, it is desirable that the ionization energy of the anode 5 be relatively high from a viewpoint of hole transport. Accordingly, the anode 5 may contain a material such as ITO, IZO, ZnO, AZO, BZO or the like in addition to the metal material described above. The group of these materials have ionization energy suitable for the hole transport and are transparent. Accordingly, light from the light-emitting layer 1 may be transmitted to a metal material having high reflectivity of visible light, which is also advantageous in terms of light extraction efficiency. The anode 5 may be formed on the array substrate 6 by using a method of depositing the material described above or a film-forming method such as sputtering.

The hole transport layer 4 is a layer for transporting positive holes from the anode 5 to the light-emitting layer 1. The hole transport layer 4 is provided on the anode 5. As the material used for the hole transport layer 4, for example, TPD, poly-TPD, PVK, TFB, CBP, or NPD is cited. The hole transport layer 4 may be formed by an application film-forming method in which the above-described material is applied and cured at a temperature, for example, lower than or equal to 100° C., a film-forming method such as sputtering and deposition, or the like.

The electron transport layer 2 is a layer for transporting electrons from the cathode 3 to the light-emitting layer 1. The electron transport layer 2 is provided on the light-emitting layer 1. As the material used for the electron transport layer 2, for example, a metal oxide such as ZnO, TiO₂ or the like, or a group II-V compound-based semiconductor is cited. The hole transport layer 4 and the electron transport layer 2 may be formed by an application film-forming method in which the above-described material is applied and cured at a temperature, for example, lower than or equal to 100° C., a film-forming method such as sputtering and deposition, or the like. The electron transport layer 2 may have a function as a barrier with respect to the positive holes.

The hole injection layer 8 is a layer for promoting the injection of the positive holes from the anode 5 to the hole transport layer 4. The hole injection layer 8 is provided between the anode 5 and the hole transport layer 4. As the material used for the hole injection layer 8, for example, PEDOT:PSS, MoO₃, NiO or the like is cited. The hole injection layer 8 may be formed, for example, by a film-forming method such as application baking, sputtering, deposition or the like.

The electron injection layer is a layer for promoting the injection of the electrons from the cathode 3 to the electron transport layer 2. The electron injection layer may be provided between the cathode 3 and the electron transport layer 2. As the material used for the electron injection layer, for example, Alq₃, PBD, TPBi, BCP, Balq, CDBP, Liq or the like is cited. The electron injection layer may be formed, for example, by a film-forming method such as application baking, sputtering, deposition or the like.

By using PEDOT:PSS for the hole injection layer 8 and using PVK for the hole transport layer 4, the transport of the positive holes from the anode 5 to the light-emitting layer 1 may be promoted. The reasons for this will be described with reference to FIG. 2. FIG. 2 is an energy band diagram of the light-emitting device 10. In FIG. 2, the longitudinal direction indicates the energy level of each of the layers in the light-emitting device 10, and the lateral direction schematically indicates a distance in the layering direction of the light-emitting device 10.

In FIG. 2, when the anode 5 is ITO, the ionization energy thereof is 4.8 eV. When the hole injection layer 8 adjacent to the anode 5 is PEDOT:PSS, the ionization energy thereof is 5.4 eV. When the hole transport layer 4 is PVK, the ionization energy thereof is 5.8 eV. When the light-emitting layer 1 adjacent to the PVK is QD, the ionization energy thereof is 5.5 eV. In the present specification, ionization energy and electron affinity are based on the vacuum level.

Because a difference in ionization energy between each of the layers from the anode 5 to the light-emitting layer 1 becomes a barrier with respect to the hole transport, it is required that the difference in ionization energy between each of the layers from the anode 5 to the light-emitting layer 1 is small or none in order to promote the hole transport from the anode 5 to the light-emitting layer 1. The ionization energy of PEDOT:PSS is 5.4 eV, the ionization energy of PVK is 5.8 eV, and the ionization energy of QD is 5.5 eV. Thus, the difference in ionization energy between QD and PEDOT:PSS is 0.1 eV, and the difference in ionization energy between QD and PVK is 0.3 eV. In this manner, by using PEDOT:PSS for the hole injection layer 8 and using PVK for the hole transport layer 4, the transport of the positive holes from the anode 5 to the light-emitting layer 1 may be promoted.

Accordingly, in addition to the above-described materials, a semiconductor having the same value of ionization energy as that of the ionization energy of the light-emitting layer 1, or a value close to that of the ionization energy of the light-emitting layer 1 may be used as the material of the hole injection layer 8 and the hole transport layer 4. As such semiconductor, for example, a metal oxide such as NiO, Cr₂O₃ or the like, or a p-type group II-VI compound semiconductor or the like is cited. The hole injection layer 8 and the hole transport layer 4 may have a function as a barrier with respect to electrons.

Because a difference in electron affinity between each of the layers from the cathode 3 to the light-emitting layer 1 becomes a barrier with respect to electron transportation, it is required that the difference in electron affinity between each of the layers from the cathode 3 to the light-emitting layer 1 is small or none in order to promote electron transportation from the cathode 3 to the light-emitting layer 1. Accordingly, it is preferable that the electron affinity of the material used for the electron transport layer 2 have the same value as, or a value close to the value of the electron affinity of the light-emitting layer 1.

In FIG. 2, when ZnO is used as the electron transport layer 2, the electron affinity thereof is 3.9 eV, while the electron affinity of QD, which is the light-emitting layer 1, is 2.7 eV; thus, a difference between them is relatively large. Accordingly, when ZnO is used as the material of the electron transport layer 2, it is preferable to improve electron transportation from the electron transport layer 2 to the light-emitting layer 1 by reducing the film thickness of the electron transport layer 2 as compared to a case of using a material having electron affinity closer to the electron affinity of QD relative to ZnO.

In general, depending on mobility and free electron concentration of ZnO, the mobility of a material in the form of layer is not greater than 10⁻⁴ Ω·cm, which is considerably low compared to a bulk material, and the free electron concentration is also low, so that the series resistance becomes high. Due to this, the film thickness of the electron transport layer 2 affects the electron transportation to the light-emitting layer 1. Therefore, when ZnO is used as the material of the electron transport layer 2, the film thickness of the electron transport layer 2 is set to be, for example, in a range of 10 nm or greater and 50 nm or less.

When the light-emitting device 10 has a top-emitting structure, the electron transport layer 2 is optically transparent in order to extract light from the electron transport layer 2 side. In order to prevent the total reflection of light from the light-emitting layer 1 at the boundary between the electron transport layer 2 and the cathode 3, a difference in the refractive index between the electron transport layer 2 and the cathode 3 is preferably small. The refractive index in the present specification refers to a refractive index with respect to visible light of a wavelength in a range of 440 nm or greater and 660 nm or less. In addition, in the present specification, the refractive index of each of the layers is intended to be an average refractive index of each of the layers in the lateral direction, that is, in a plane direction. Details of the refractive index difference between the electron transport layer 2 and the cathode 3 will be described below.

The light-emitting element 7 is an organic light-emitting diode (OLED) or a quantum dot light-emitting diode (QLED). The OLED includes a light-emitting layer containing an organic material that performs a fluorescent light emission or a phosphorescent light emission. The QLED includes a light-emitting layer in which one to multiple layers of quantum dots each provided with a core and a shell covering the core are layered. In the present embodiment, a case in which the light-emitting element 7 is a QLED is described as an example. Therefore, the light-emitting layer 1 is a quantum dot layer.

The quantum dot layer contains a plurality of quantum dots (semiconductor nanoparticles). The quantum dot is a light-emitting material that has valence band energy and conduction band energy, and emits light by recombination of positive holes of the valence band energy and electrons of the conduction band energy. Because light emitted from the quantum dot has a narrower spectrum due to a quantum confinement effect, it is possible to obtain light emission with relatively deep chromaticity.

An example of the quantum dot may include semiconductor nanoparticles having a core/shell structure including CdSe in the core and ZnS in the shell. In addition to this, the quantum dot may include CdSe/CdS, InP/ZnS, ZnSe/ZnS, CIGS/ZnS, or the like as the core/shell structure. In order to confine electrons and positive holes in the core, the shell preferably has a wider band gap than the core, and, for example, the shell is preferably ZnS. The quantum dot may include a ligand coordinated with the shell.

A quantum dot particle size may be approximately 3 to 15 nm. A light emission wavelength from the quantum dot may be controlled by the particle size of the quantum dot. Thus, the wavelength of the light emitted by the light-emitting device 10 may be controlled through the control of the particle size of the quantum dot.

The quantum dot layer may be film-formed by a spin coating method, an ink-jet method, or the like using a dispersion liquid in which quantum dots are dispersed in a solvent such as hexane, toluene or the like. The dispersion liquid may be mixed with a dispersion material such as thiol, amine or the like. The quantum dot layer may have the quantum dots dispersed in a resist, and may be patterned by photolithography. The electrons and positive holes transported to the quantum dot layer are present in the same space within the quantum dot layer, whereby the light emission recombination is efficiently performed. Therefore, it is preferable for the concentration distribution of the transported electrons and positive holes not to be largely separated in a layer thickness direction due to a difference in effective mass therebetween. The film thickness of the quantum dot layer is preferably in a range of 10 nm or greater and 50 nm or less.

The cathode 3 injects electrons into the electron transport layer 2. The cathode 3 is provided on the electron transport layer 2, and is electrically connected to the electron transport layer 2. In the light-emitting device 10, the main component of the cathode 3 is a metal boride. Herein, the “main component of the cathode” refers to a component that makes up the highest percentage of the total components constituting the cathode 3. The content of the metal boride in the cathode 3 is preferably not less than 10 mass %, and more preferably not less than 40 mass % to the total amount of all components constituting the cathode 3, taking into account the resistance value in the thickness direction of the cathode 3 with respect to the electrons transported from the cathode 3 to the light-emitting layer 1. The resistance value in the thickness direction of the cathode 3 containing 10 mass % of the metal boride is lowered by about 10%, and the resistance value in the thickness direction of the cathode 3 containing 40 mass % of the metal boride is lowered by about 50% with respect to the resistance value in the thickness direction of the cathode in a case of containing no metal boride. The upper limit of the content of the metal boride in the cathode 3 is not particularly limited; as the content of the metal boride is increased, the electron injection becomes more preferable.

Among the metal borides, a diboride is a hexagonal crystal and a hexaboride is a cubic crystal; when any of them is thinned, a crystal face made of a metal element and a crystal face made of boron are oriented to be alternately arranged in the film thickness direction. Therefore, in the film containing the metal boride, a columnar structure of the metal boride is locally formed inside a plane of the film, and the electrons are transported through the columnar structure. Accordingly, when the content of the metal boride contained in the cathode 3 is 10 mass % or greater, the columnar structure of the metal boride passing through the thin film in the thickness direction is sufficiently formed, so that the electron injection is preferably performed in a desired manner. When the content of the metal boride contained in the cathode 3 is 40 mass % or greater, the columnar structure is more sufficiently formed, and more desirable electrode injection may be achieved. By forming the columnar structure of the metal boride, the resistance value in the thickness direction of the cathode 3 containing 10 mass % of the metal boride is lowered about 10%, and the resistance value in the thickness direction of the cathode 3 containing 40 mass % of the metal boride is lowered about 50%.

The cathode 3 may further contain other components in addition to the metal boride. The cathode 3 may contain, in addition to the metal boride, a metal material such as Al, Ag, MgAg or the like, for example. Further, the cathode 3 may contain, for example, a transparent oxide such as ITO, IZO, ZAO, ISO or the like in addition to the metal boride.

It is preferable that the metal boride, which is the main component of the cathode 3, be MB₂ₙ when the metal element is represented by M and boron is represented by B (note that n is an integer) in view of electron transportation based on the crystal structure of the metal boride. In such metal boride, examples of M include La or Zr. The metal boride in which M is La or Zr exhibits metallic electrical conduction, and has a band gap between the valence band and the conduction band to exhibit characteristics of a semiconductor. On the other hand, because of the narrow band gap of the metal boride in which M is La or Zr, electrons (free electrons) are directly supplied from the valence band to the conduction band. Because of this, the metal boride in which M is La or Zr has a high free electron density comparable to a metal, and the sheet resistance value thereof is approximately tens of Ω, so as to be suitable for electron transportation.

Note that n represents an integer equal to or greater than one; for example, in a case of M being La, n is equal to three to six, and in a case of M being Zr, n is equal to one. It is preferable for MB₂ₙ, which is a metal boride, to be any one of LaB₆, LaB₁₀, LaB₁₂, and ZrB₂ in view of the crystal structure thereof and electron transportation. When the metal boride has such a crystal structure that there exists a direction in which a crystal face made of a metal element and a crystal face made of boron are alternately arranged, electrons are likely to be transported in that direction. A factor causing the crystal face made of the metal element and the crystal face made of boron to be alternately arranged is strong ionicity of boron; when the number of elements of boron is 2n, a hexagonal crystal is formed, and when the number of elements of boron is 3n, a cubic crystal is formed. A (0001) direction of the hexagonal crystal and a (001) direction of the cubic crystal are directions suitable for transporting the electrons. In a case where the metal boride is thinned, because the above-described directions have a property of being easily oriented in the film thickness direction, the metal borides of the above-described numbers of elements are particularly preferred from a viewpoint that the electrical characteristics suitable for the cathode material of the light-emitting element can be obtained.

The cathode 3 preferably has a small work function from the viewpoint of efficient electron transportation to the light-emitting layer 1. In addition, because the energy difference between the work function of the cathode 3 and the electron affinity of the electron transport layer 2 becomes a barrier with respect to the electron injection from the cathode 3 to the electron transport layer 2, it is preferable for the energy difference between the work function of the cathode 3 and the electron affinity of the electron transport layer 2 to be small or to be none. Therefore, it is preferable that the work function of the cathode 3 be small, and is preferable that a difference between the above work function and the electron affinity of the electron transport layer 2 be small.

The work function of the cathode 3, and a relationship between the work function of the cathode 3 and the electron affinity of the electron transport layer 2 will be described while comparing the light-emitting device 10 according to the present embodiment in FIG. 1 with a known light-emitting device 20 in FIG. 4. FIG. 4 is a schematic cross-sectional view of a light-emitting device according to a comparative example. The light-emitting device 20 includes a light-emitting element 27 having an anode 25, a hole injection layer 28, a hole transport layer 24, a light-emitting layer 21, an electron transport layer 22, and a cathode 23 in that order on an array substrate 26. The light-emitting device 20 is different from the light-emitting device 10 in that the material of the cathode 23 is Al.

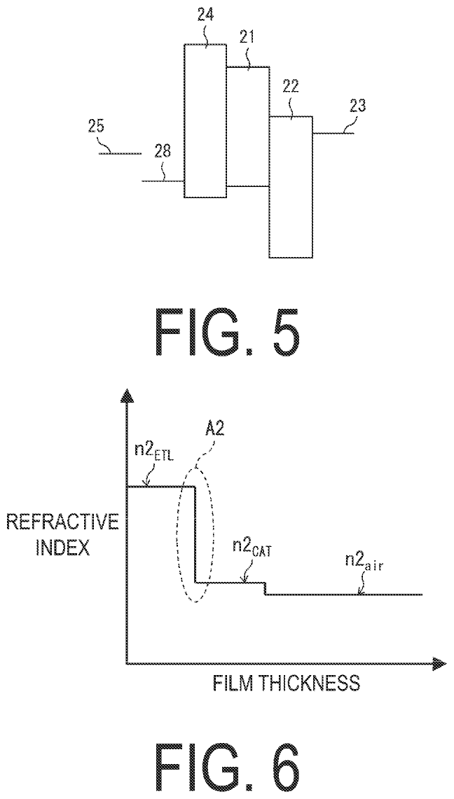

The energy level of each of the layers of the light-emitting device 10 and the light-emitting device 20 will be described with reference to FIGS. 2 and 5. FIG. 5 is an energy band diagram of the light-emitting device according to the comparative example. In FIG. 5, the longitudinal direction indicates the energy level of each of the layers in the light-emitting device 20, and the lateral direction schematically indicates a distance in the layering direction of the light-emitting device 20.

In FIG. 5, when the cathode 23 is Al, the work function thereof is 4.3 eV. When the electron transport layer 22 is ZnO, the electron affinity thereof is 3.9. Thus, in the light-emitting device 20, a difference between the work function of the cathode 23 and the electron affinity of the electron transport layer 22 is 0.4 eV.

On the other hand, in the light-emitting device 10 according to the present embodiment, the main component of the cathode 3 is a metal boride. In FIG. 2, when the cathode 3 (32) is ZrB₂, the work function thereof is 3.8; when the cathode 3 (33) is LaB₆, the work function is 2.8. Thus, the cathode 3 containing ZrB₂ or LaB₆ as the main component has a smaller work function than the cathode 23 containing Al. Accordingly, electron transportation to the light-emitting layer 1 can be made more efficient. In addition, a difference between the work function 3.8 of the cathode 3 (32) containing ZrB₂ as the main component and the electron affinity 3.9 of the electron transport layer 2 made of ZnO is 0.1, which is small compared to the case of the cathode 23 containing Al. Accordingly, electrons may efficiently be injected from the cathode 3 to the electron transport layer 2.

In the case where quantum dots are contained in the light-emitting layer, the wavelength of emitted light decreases as the particle size of the quantum dots is reduced, but in this case as well, the ionization energy of the light-emitting layer 1 is hardly changed, and only the electron affinity becomes small. When the quantum dot has, for example, a ZnSe core/ZnS shell structure, the electron affinity of the light-emitting layer decreases as the wavelength of the emitted light becomes shorter in sequence of red, green, and blue, whereby the barrier between the light-emitting layer and the electron transport layer becomes large, and electron transportation becomes difficult. Even a quantum dot of a different structure like a quantum dot including an InP core that does not contain Cd, for example, exhibits the same tendency. Because the cathode 3 contains, as the main component, a metal boride having a smaller work function than Al, even when the light-emitting layer 1 containing quantum dots configured to emit light with a short wavelength is used, the difference between the electron affinity of the light-emitting layer 1 and the work function of the cathode 3 may be made smaller than the case of the cathode 23 containing Al. Because of this, the light-emitting device 10 exhibits a more prominent effect in the case of including a light-emitting layer containing quantum dots configured to emit light with a short wavelength.

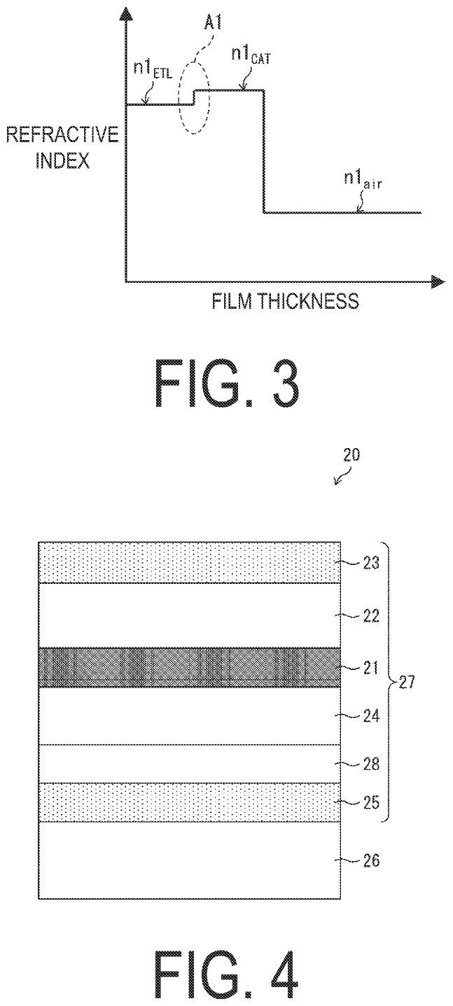

It is advantageous for the cathode 3 to contain the metal boride as the main component from a viewpoint of light extraction efficiency, as described below. The light extraction efficiency of the cathode 3 will be described below while comparing FIG. 3 illustrating refractive index distribution of the light-emitting device 10 according to the present embodiment, with FIG. 6 illustrating refractive index distribution of the known light-emitting device 20. FIG. 3 is a refractive index distribution diagram illustrating the refractive index distribution in the layer thickness direction of the light-emitting device 10, and FIG. 6 is a refractive index distribution diagram illustrating the refractive index distribution in the layer thickness direction of the light-emitting device 20.

As illustrated in FIG. 6, in the light-emitting device 20, a refractive index n2_{CAT} of the cathode 23 containing Al is 1.3, and a refractive index n2_{ETL} of the electron transport layer 22 made of ZnO is 2. Accordingly, the refractive index difference at an interface between the cathode 23 and the electron transport layer 22 indicated in a region A2 is 0.7.

On the other hand, as illustrated in FIG. 3, in the light-emitting device 10, a refractive index n1_{CAT} of the cathode 3 containing ZrB₂ and LaB₆ as metal borides is 2.2, and a refractive index n1_{ETL} of the electron transport layer 2 made of ZnO is 2. Accordingly, the refractive index difference at an interface between the cathode 3 and the electron transport layer 2 indicated in a region A1 is 0.2.

The larger the refractive index difference between adjacent layers, the more easily the light from the light-emitting layer is reflected at the interface, so that the light extraction efficiency of the light-emitting device is lowered. Because the cathode 3 containing the metal boride has a smaller refractive index difference with the electron transport layer 2 than the cathode 23 containing Al, the reflection at the interface with the electron transport layer 2 is suppressed, and thus the light extraction efficiency is improved.

Furthermore, because the cathode 3 contains metal boride as the main component, the advantage that the electron injection efficiency is high from the viewpoint of the work function is obtained as described above, and also advantages from the viewpoint of the transmittance of light from the light-emitting layer 1 and the oxidation prevention of the surface on the electron transport layer 2 side are obtained. For example, the work function of Mg used as the known cathode is 3.7, which is less than the work function of ZrB₂; however, when the cathodes 3 having the same film thickness are formed, ZrB₂ exhibits a higher transmittance of light from the light-emitting layer 1 than Mg. Furthermore, Mg is easily oxidized because of being an alkali metal, and has poor long-term stability. Due to this, Mg in the cathode is easily oxidized at a contact interface between the electron transport layer containing oxide and the cathode, and there arises a fear that the electrical characteristics of the light-emitting device are degraded.

On the other hand, in the cathode 3 containing the metal boride, because light transmittance in a visible range and in an infrared region is greater than or equal to 80% with a film thickness of 1 μm, the light transmittance thereof with respect to light in the visible range and in the infrared region is high compared to the cathode containing Mg with the same film thickness. Furthermore, the metal boride is a compound having a strong bond, and therefore it is unlikely to be oxidized even at the contact interface with the electron transport layer 2 including oxide, and the problems described above are unlikely to arise.

The metal boride has high mechanical strength because of having a strong bond. The Vickers hardness of the metal boride is substantially 10 to 20 GHV, which is about 10 times the Vickers hardness of 2 to 3 GHV of mother glass for a display panel. Therefore, in the manufacturing process of the display panel, when the surface of the light-emitting device 10 is covered with the cathode 3 made of the metal boride, an effect of protecting the internal element structure from the external force in the subsequent manufacturing process is large. Because the mechanical strength of the metal boride is significantly high, it is unnecessary to provide a sealing material for imparting mechanical strength to the light-emitting device. Thus, the provision of a sealing material and the sealing process for obtaining the mechanical strength may be omitted in comparison with the known light-emitting device.

The cathode 3 may be formed by a film-forming method such as application baking, sputtering, deposition or the like. Sputtering is preferable as the film-forming method for the cathode 3 because a dense film formed of an aggregate of microcrystals is produced in the manner in which Ar ions are collided with one another and emitted target substances are attached to the substrate. In the application baking, nanoparticle colloid of the metal boride may be used.

In the cathode 3, the maximum value of the thickness from the upper face to the end face on the electron transport layer side is preferably 1 μm or less. That is, the thickness of any portion of the cathode 3 is preferably 1 μm or less. As long as the film thickness of the cathode 3 is 1 μm or less, the light transmittance of the metal boride configured to transmit light from the light-emitting layer 1 is generally greater than 80%, so that it is possible to prevent a reduction in light extraction efficiency caused by a situation in which the light from the light-emitting layer 1 is absorbed in the cathode 3.

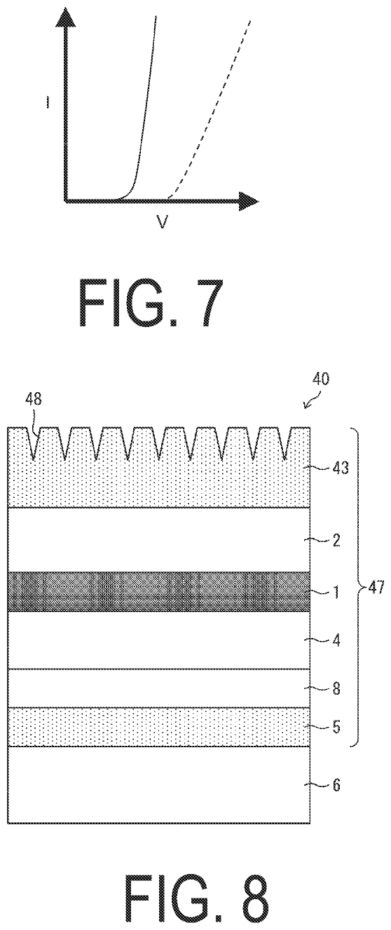

The electrical characteristics when the light-emitting device 10, in which the main component of the cathode 3 is LaB₆, is energized will be described below with reference to FIG. 7. FIG. 7 is a graph comparing the electrical characteristics between the light-emitting device 10 according to the first embodiment and the light-emitting device 20 according to the comparative example. In FIG. 7, the horizontal axis represents a voltage, the vertical axis represents a current, the solid line represents the value of the light-emitting device 10, and the broken line represents the value of the light-emitting device 20.

As indicated by the solid line in FIG. 7, I-V of the light-emitting device 10 depicted diode characteristics. A threshold voltage of the light-emitting device 10 was 1.9 V, which was lower than that of the known light-emitting device 20 by 1 V or greater. The electrical characteristics of the above-described light-emitting device 10 may be brought by the fact that the contact resistance between the cathode 3 containing the metal boride as the main component and the electron transport layer 2 is low, and the work function of the cathode 3 is less than the electron affinity of the electron transport layer 2, thereby causing contact between the cathode 3 and the electron transport layer 2 to be ohmic contact with small resistance.

The light extraction efficiency was calculated for the light-emitting device 10 and the light-emitting device 20; as a result, the light extraction efficiency of the light-emitting device 10 was 15% exhibiting improvement as compared to 12% of the light extraction efficiency of the light-emitting device 20. This improvement in light emission characteristics may be brought by an increase in electrons transported to the light-emitting layer 1 due to a small work function and high electrical conductivity held by the metal boride of the cathode 3. A similar improvement in characteristics was also observed for the cathode 3 containing ZrB₂ as the main component.

It is known that it is difficult to directly measure the light extraction efficiency of a light-emitting device by using an actual element. Thus, the light extraction efficiency of the light-emitting device is generally determined by optical simulation. In this case, the light extraction efficiency of the light-emitting device 10 and the light-emitting device 20 described above was calculated by a ray tracing method. The ray tracing method is a method in which a light-emitting layer is divided into micro-regions in a mesh-like form, and the Lambert's law of radiation representing that light is uniformly emitted from each of the micro-regions in all directions, the Lambert-Beer's law regarding light absorption, and the Snell's law regarding a traveling direction of a refractive index interface are used for tracing the propagation of light beams in a geometrical-optical manner. This approach determines the proportion of light beams, among the light beams from the light-emitting layer set as the initial condition, that reach the outside of the light-emitting device.

### Second Embodiment

FIG. 8 is a schematic cross-sectional view of a light-emitting device 40 according to the present embodiment. As illustrated in FIG. 8, the light-emitting device 40 differs from the light-emitting device 10 of the embodiment described above in that the light-emitting device 40 is provided with a light-emitting element 47 including a cathode 43 having an opening 48 formed therein. Note that, for convenience of description, members having the same functions as those of the members described in the above-described embodiment will be denoted by the same reference signs, and the description thereof will not be repeated.

The upper face of the cathode 43 is opened to have the opening 48. In other words, in an end face of the cathode 43 on the opposite side to the electron transport layer 2, there is formed the opening 48 being opened from the end face toward an end face of the cathode 43 on the electron transport layer 2 side. The cathode 43 is different from the cathode 3 of the embodiment described above in only a point that the cathode 43 has the opening 48. The light-emitting element 47 differs from the light-emitting element 7 of the embodiment described above in only a point that the light-emitting element 47 includes the cathode 43.

As illustrated in FIG. 3, in the light-emitting device 10, the refractive index n1_{CAT} of the cathode 3 containing ZrB₂ and LaB₆ as the main components is 2.2, and the refractive index n1_{ETL} of the electron transport layer 2 made of ZnO is 2. Accordingly, when an air refractive index n1ₐᵢᵣ is assumed to be 1, the refractive index distribution in a layer thickness direction of the light-emitting device 10 is stepwise.

FIG. 9 illustrates refractive index distribution of the light-emitting device 40. In the light-emitting device 40, the material of the electron transport layer 2 and the cathode 43 is the same as the material of the electron transport layer 2 and the cathode 3 of the light-emitting device 10. Thus, in the light-emitting device 40, a refractive index difference at the interface between the electron transport layer 2 and the cathode 43 indicated in a region A3 is the same as the refractive index difference at the interface between the electron transport layer 2 and the cathode 3. Accordingly, in the light-emitting device 40, light from a light-emitting layer 1 is unlikely to be reflected at the interface between the electron transport layer 2 and the cathode 43, so that light extraction efficiency is not lowered.

As illustrated in FIG. 6, in the known light-emitting device 20 with the cathode 23 containing Al as its main component, the refractive index n2_{CAT} of the cathode 23 is 1.3, and the refractive index n2_{ETL} of the electron transport layer 22 made of ZnO is 2. Thus, the difference in the refractive index at the interface between the electron transport layer 22 and the cathode 23 indicated in the region A2 is 0.7. Therefore, the reflection of light that comes from the light-emitting layer 1 occurs at the interface between the electron transport layer 2 and the cathode 23, so that the light extraction efficiency is lowered.

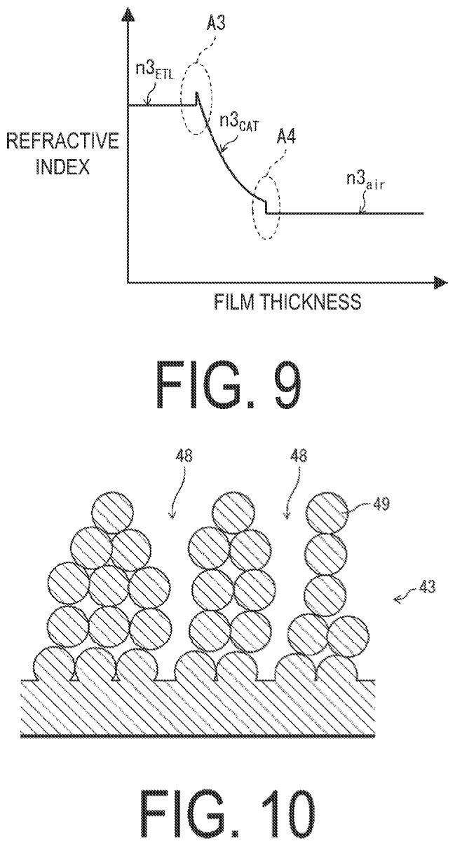

Next, a relationship of refractive indices at the interface between the cathode and the air will be described with reference to FIGS. 3 and 10. As indicated in FIG. 3, the refractive index n1_{CAT} of the cathode 3 is 2.2; therefore, when the air refractive index n1ₐᵢᵣ is assumed to be 1, the refractive index difference at the interface between the cathode 3 and the air is larger than the refractive index difference at the interface between the electron transport layer 2 and the cathode 3.

In contrast, as indicated in FIG. 9, a refractive index n3_{CAT} of the cathode 43 in the light-emitting device 40 is 2.2 on a side of the region A3 in contact with the electron transport layer 2, and is 1.2 on a side of a region A4 in contact with the air. As described above, the refractive index of the cathode 43 is different between the side in contact with the electron transport layer 2 and the side in contact with the air.

The cathode 43 has the opening 48, where the upper face of the cathode 43, in other words, the interface between the cathode 43 and the air is open. This causes the refractive index of the cathode 43 at the interface with the air to be smaller than the refractive index thereof at the interface with the electron transport layer 2. In FIG. 9, the refractive index n3_{CAT} of the cathode 43 at the interface with the air is 1.2, and when an air refractive index n3ₐᵢᵣ is assumed to be 1, the difference therebetween is 0.2. As a result, in the light-emitting device 40, light from the light-emitting layer 1 is unlikely to be reflected at the interface between the cathode and the air, and the light extraction efficiency is not lowered in comparison with the light-emitting device 10. Further, in the cathode 43, the refractive index n3_{CAT} at the interface with the electron transport layer 2 is 2.2, and the refractive index n3_{ETL} of the electron transport layer 2 is 2, so that the difference therebetween is 0.2. Because of this, the light from the light-emitting layer 1 is unlikely to be reflected at the interface between the electron transport layer 2 and the cathode 43, so that the light extraction efficiency is not lowered.

As described above, by varying the refractive index of the cathode 43 on the electron transport layer 2 side and the air side, the light extraction efficiency at each of the interfaces may be improved.

Hereinafter, the configuration of the opening 48 of the cathode 43 is described with reference to FIG. 10. FIG. 10 is a schematic cross-sectional view enlarging part of the cathode 43 included in the light-emitting device 40. As illustrated in FIG. 10, the cathode 43 is constituted by an aggregate of particles 49 of metal borides, and has a porous structure having the opening 48 in the upper face thereof. In the cathode 43, the metal boride particle 49 and the opening 48 are adjacent to each other at a distance of 450 nm or less, which is the shortest light wavelength of the light incident on the cathode 43.

As described above, because the cathode 43 has the porous structure and the pore size of the porous structure is equal to or smaller than the wavelength of the light incident on the cathode 43, the refractive index that the incident light undergoes is the average of refractive indices of the pore and a medium around the pore in consideration of each of the volumes of the pores. This average refractive index may be obtained by the product of volume ratios occupied by the pores in a unit volume, and the product of a refractive index and a volume ratio (=1−volume ratio of the pores) of the portion excluding the pores. Because the pore included in the porous structure is occupied by the air, a vacuum, or a gas for sealing the light-emitting element, the refractive index thereof is 1. Thus, the refractive index that the light incident on the cathode 43 undergoes may be determined by the refractive index of the metal boride as the peripheral medium. As described above, by having the porous structure, the refractive index that the light incident on the cathode 43 substantially receives is lowered.

For example, in a case where a cross-sectional area of the opening 48 and a cross-sectional area of the metal boride particle 49 are equal in the cross section of the cathode 43 cut in a layering direction, the refractive index at the corresponding location is reduced to approximately 1.2. When the refractive index of the air is assumed to be 1, the total reflection angle of the cathode 43 and the air is 56 degrees. On the other hand, as in the light-emitting device 10 of the above-described embodiment, the cathode 3 without the opening has a refractive index of 2.2, and thus the total reflection angle of the cathode 3 and the air is 30 degrees. As described above, the total reflection angle of the cathode 43 having the opening 48 and the air is larger than that of the cathode without an opening, and thus the effect of the total reflection at the interface between the cathode 43 and the air may be reduced, and the light extraction efficiency may be improved. The light extraction efficiency of the light-emitting device 40 provided with the cathode 43 having the opening 48 was calculated using the above-described ray tracing method, and the calculation result showed that the light extraction efficiency was improved to be 21% in comparison with the light-emitting device 10 and the light-emitting device 20.

The opening 48 need not communicate from the upper face of the cathode 43 to the end face thereof on the electron transport layer 2 side. In other words, the face on the cathode 43 side of the electron transport layer 2 may be covered with a continuous film of the cathode 43, in which no opening is formed.

When the cathode has a porous structure uniform in the layer thickness direction, and the opening reaches the interface between the cathode and the electron transport layer, there arises a risk that the light from the light-emitting layer is reflected at the interface between the cathode and the electron transport layer by the refractive index of the entire cathode being lowered. Furthermore, when the opening reaches the interface between the cathode and the electron transport layer, electron injection efficiency may be different between a portion where the cathode is open and a portion where the cathode is not open, so that there is a possibility that the electron injection is not performed uniformly at the entire interface between the cathode and the electron transport layer.

In the cathode 43, the opening 48 does not reach the interface with the electron transport layer 2, and the electron transport layer 2 is covered with the continuous film of the cathode 43. Thus, a situation in which the light from the light-emitting layer 1 is reflected at the interface between the cathode 43 and the electron transport layer 2 is suppressed, and the electron injection from the cathode 43 to the electron transport layer 2 is not hindered by the opening 48.

The end face on the electron transport layer 2 side of the cathode 43 is preferably a continuous film in a range of 5 nm or greater and 20 nm or less from the interface with the electron transport layer 2 from the viewpoint of suppressing the reflection of light from the light-emitting layer 1 toward the electron transport layer 2 side. In the case where there is a continuous film in the above-described range from the interface with the electron transport layer 2 in the cathode 43, the light from the light-emitting layer 1 undergoes the metal boride refractive index at the interface, and thus the light reflection at the interface may be suppressed, and the light may be incident on cathode 43.

In this case, in the cathode 43, a porous structure having the opening 48 is provided in a range extending more than 20 nm and less than or equal to 1 μm from the interface with the electron transport layer 2. In the cathode 43 containing the metal boride, the transmittance of light in a visible range and in an infrared region is greater than or equal to 80% with a film thickness of 1 μm, and the transmittance of light in the visible range and in the infrared region is lowered when the film thickness exceeds 1 μm. Therefore, the upper limit of the film thickness of the cathode 43 is preferably 1 μm.

By the cathode 43 having the opening 48, external light incident on the cathode 43 from the outside of the light-emitting device 40 scatters in all directions at the face of the opening 48. As a result, the scattering of the external light at the surface of the cathode 43 takes a halo shape, and the glare is suppressed. That is, in the cathode 43, because the scattering of the external light does not depend on the directions, the appearance does not change depending on the viewing angle.

The refractive index of the cathode 43 preferably decreases from the electron transport layer 2 side toward the upper side. As described above, by continuously changing the refractive index from the electron transport layer 2 side toward the upper side, loss of light passing through the cathode 43 may be suppressed. This is because a discontinuous change of the refractive index causes light reflection at the discontinuous interface.

An area of the opening 48 in a top view of the cathode 43 preferably decreases from the upper face side toward the electron transport layer 2 side. In this manner, the opening 48 has a moth-eye shape that gradually tapers from the upper face side of the cathode 43 toward the electron transport layer 2 side thereof, and thus the cathode 43 may have a refractive index distribution such that the refractive index becomes continuously smaller from the lower side toward the upper side. This makes it possible to obtain an effect of suppressing transmission loss of light in the cathode 43.

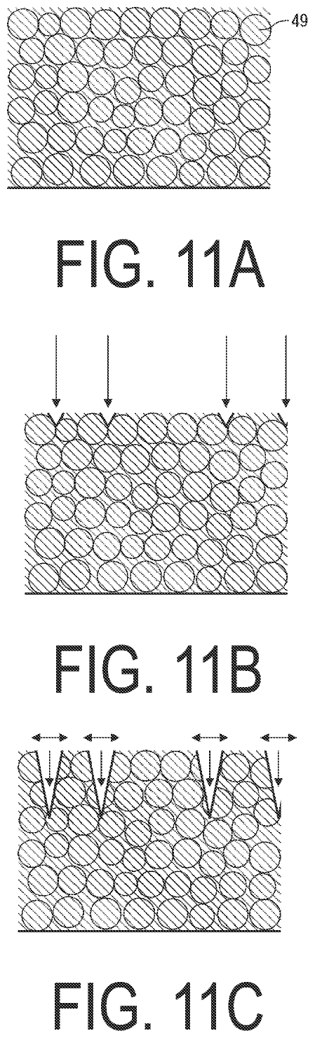

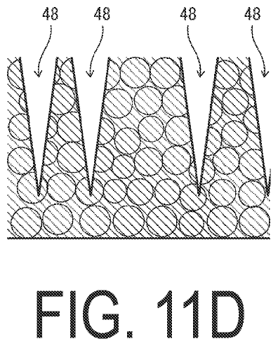

Referring now to FIGS. 11A to 11D, a step of forming the cathode 43 having the opening 48 will be described. FIGS. 11A to 11D are diagrams describing a step of forming the cathode included in the light-emitting device according to the second embodiment of the disclosure. As the step of forming the cathode 43, an example of using etching by acid is described in the present embodiment. An MB₂ₙ type metal boride is well soluble in sulfuric acid, hydrochloric acid, and the like. Accordingly, etching by acid such as sulfuric acid, hydrochloric acid and the like may easily form the cathode 43 having the opening 48.

First, as illustrated in FIG. 11A, a continuous film including the metal boride particles 49 is formed by sputtering, for example. The continuous film formed by sputtering is formed of an aggregate of the microparticles, so that there is a fine grain boundary between the adjacent particles 49. Subsequently, as illustrated in FIG. 11B, acid is applied from the upper face of the continuous film. The etching by acid preferentially proceeds from the grain boundary of the continuous film. The orientation directions of the particles 49 in the continuous film are in disorder, that is, the particles are not oriented in a specific direction, and the etching by the acid is isotropic; accordingly, as indicated by arrows in FIG. 11C, the etching speed in the layer thickness direction and the etching speed in an in-plane direction are substantially equal to each other, and the erosion is caused in all directions. Thus, as illustrated in FIG. 11D, a cavity made by the etching is formed in such a manner as to be large on the upper face side of the cathode 43 and to become small toward the electron transport layer 2 side. The depth of erosion by the etching may be controlled by the erosion time.

As another method of forming the opening 48 in the cathode 43, for example, a method of applying a colloidal solution in which metal boride particles having different particle sizes are dispersed in a multilayer form may be cited.

### Modified Example

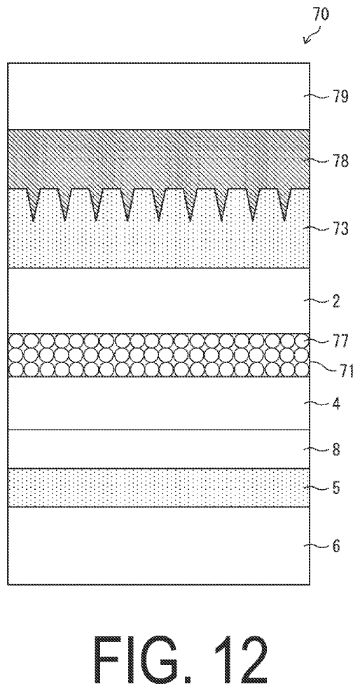

FIG. 12 is a schematic cross-sectional view of a modified example of a light-emitting device according to the second embodiment of the disclosure. As illustrated in FIG. 12, a light-emitting device 70 includes a sealing layer 78 provided on a cathode 73. By forming the sealing layer 78 using a material having a high waterproof effect, high strength, or the like, the light-emitting device 70 may enhance the waterproof effect or the strength. Further, an opening provided on an upper face of the cathode 73 is filled with the sealing layer 78. This brings an advantage that the sealing of an electron transport layer 2 may be enhanced. When a material having a low refractive index is used as the material of the sealing layer 78, with which the opening provided on the upper face of the cathode 73 is filled, the average refractive index of the cathode 73 may be more preferably lowered. Furthermore, a substrate 79, which is a CF substrate, is provided on the sealing layer 78, for example, in contact with the sealing layer 78. This brings an advantage that a difference in the refractive index across from the sealing layer 78 to the CF substrate may be reduced. A light-emitting layer 71 of the light-emitting device 70 is a quantum dot layer containing quantum dots 77. Other configurations of the light-emitting device 70 are the same as those of the light-emitting device 40.

As the material of the sealing layer 78, for example, an inorganic layer of SiN, SiON, Al₂O₃ or the like, or a resin layer may be cited. When the cathode 73 and the sealing layer 78 are in contact with each other as in the light-emitting device 70, it is preferable that the refractive index of the end face on the sealing layer 78 side in the cathode 73 have a value slightly different from a value of the refractive index of the sealing layer 78. This prevents the light from the light-emitting layer 71 from being reflected at the interface between the cathode 73 and the sealing layer 78, and improves the light extraction efficiency. In addition, it is preferable for the refractive index of the cathode 73 to decrease from the electron transport layer 2 side toward the sealing layer 78 side. This allows a change in the refractive index from the light-emitting layer 71 to the sealing layer 78 to be gentle, which is preferable from a viewpoint of suppressing the propagation loss of light in the light-emitting device.

### Supplement

The light-emitting device 10 according to a first aspect of the disclosure includes the light-emitting layer 1, the electron transport layer 2 provided on the light-emitting layer 1, and the cathode 3 provided on the electron transport layer 2, and a main component of the cathode 3 is a metal boride. With this, because the work function of the cathode 3 is small, and a difference between the work function of the cathode 3 and electron affinity of the electron transport layer 2 is reduced, electrons may be efficiently injected from the cathode 3 into the electron transport layer 2.

The light-emitting device 40 according to a second aspect of the disclosure is such that, in the first aspect, the refractive index of the cathode 43 may be smaller from the electron transport layer 2 side toward the upper side. This allows a change in the refractive index from the light-emitting layer 1 to the cathode 43 to be gentle. As a result, the light emitted by the light-emitting layer 1 may be prevented from being totally reflected at the interface between each of the layers in the light-emitting device 40, and the light extraction efficiency from the light-emitting device 40 may be improved.

The light-emitting device 70 according to a third aspect of the disclosure may further include the sealing layer 78 provided on the cathode 73 in the first or second aspect, and the refractive index of the cathode 73 may be smaller from the electron transport layer 2 side toward the sealing layer 78. This allows a change in the refractive index of the cathode 73 to be gentle. As a result, the light emitted by the light-emitting layer 1 may be prevented from being totally reflected at the interface between each of the layers in the light-emitting device 70, and the light extraction efficiency from the light-emitting device 70 may be improved.

The light-emitting device 40 according to a fourth aspect of the disclosure is such that, in any one of the first to third aspects, the cathode 43 may have the opening 48, the upper face of which is open. This makes it possible to change the refractive index on the upper face of the cathode 43.

The light-emitting device 70 according to a fifth aspect of the disclosure is such that, in the fourth aspect, the opening may be filled with the sealing layer 78. This brings an advantage that the sealing of the electron transport layer 2 may be enhanced.

The light-emitting device 40 according to a sixth aspect of the disclosure is such that, in the fourth or fifth aspect, an area of the opening 48 in a top view of the cathode 43 may decrease from the upper face side toward the electron transport layer 2 side. This causes the refractive index to decrease from the lower side toward the upper side of the cathode 43. As a result, it is possible to prevent a situation in which the light from the light-emitting layer 1 is reflected at the interface between the cathode 43 and the electron transport layer 2 and at the interface between the cathode 43 and the air, and improve the light extraction efficiency.

The light-emitting device 40 according to a seventh aspect of the disclosure is such that, in any one of the first to third aspects, the face on the cathode 43 side of the electron transport layer 2 may be covered with a continuous film of the cathode 43, in which no opening is formed. With this, the injection of electrons from the cathode 43 into the electron transport layer 2 is not hindered by the opening (opening 48), and the refractive index of the cathode 43 at the interface with the electron transport layer 2 may be prevented from being lowered by the opening.

The light-emitting device 10 according to an eighth aspect of the disclosure is such that, in any one of the first to seventh aspects, the maximum value of the thickness of the cathode 3 from the upper face to the end face on the electron transport layer 2 side may be smaller than or equal to 1 μm. This makes it possible to reduce the degree of decrease in light extraction efficiency due to light absorption by the cathode 3.

The light-emitting device 10 according to a ninth aspect of the disclosure is such that, in any one of the first to eighth aspects, when a metal element is denoted by M and boron is denoted by B, the metal boride may be MB₂ₙ (where, n is an integer). This brings an advantage that the light transmittance of the cathode 3 is improved and electrical conductivity is obtained at the same time.

The light-emitting device 10 according to a tenth aspect of the disclosure is such that, in the ninth aspect, the MB₂ₙ may be any of LaB₆, LaB₁₀, LaB₁₂, and ZrB₂. This brings an advantage of improving the electron transport property of the cathode 3.

The light-emitting device 10 according to an eleventh aspect of the disclosure is such that, in any one of the first to tenth aspects, the light-emitting layer 1 may contain quantum dots. In the case where the quantum dots are contained in the light-emitting layer 1, the electron transportation to the light-emitting layer 1 configured to emit light of a short wavelength is likely to be reduced; however, in the disclosure, such a problem is unlikely to occur even when the light-emitting layer 1 contains the quantum dots. Completely, the disclosure exhibits a prominent effect when the quantum dots are contained in the light-emitting layer 1.

The light-emitting device 10 according to a twelfth aspect of the disclosure is such that, in any one of the first to eleventh aspects, a main component of the electron transport layer 2 may be zinc oxide. This brings an advantage that the junction between the electron transport layer 2 and the cathode 3 may be made to be a thin Schottky type, and the contact between the cathode 3 and the electron transport layer 2 may be made to be an ohmic contact having small resistance.

The light-emitting device 10 according to a thirteenth aspect of the disclosure is such that, in any one of the first to twelfth aspects, a work function of the cathode 3 may be smaller than or equal to a work function of the electron transport layer 2. This makes it possible to inject electrons efficiently into the electron transport layer 2.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A light-emitting device, comprising:
a light-emitting layer;
an electron transport layer provided on the light-emitting layer; and
a cathode provided on the electron transport layer,
wherein a main component of the cathode is a metal boride.

2. The light-emitting device according to claim 1,
wherein a refractive index of the cathode decreases from the electron transport layer side toward an upper side.

3. The light-emitting device according to claim 1, further comprising:
a sealing layer provided on the cathode,
wherein the refractive index of the cathode decreases from the electron transport layer side toward the sealing layer.

4. The light-emitting device according to claim 1,
wherein the cathode includes an opening whose upper face is open.

5. The light-emitting device according to claim 4,
wherein the opening is filled with a sealing layer.

6. The light-emitting device according to claim 4,
wherein an area of the opening in a top view of the cathode decreases from the upper face side toward the electron transport layer side.

7. The light-emitting device according to claim 1,
wherein a face on the cathode side of the electron transport layer is covered with a continuous film of the cathode in which no opening is formed.

8. The light-emitting device according to claim 1,
wherein a maximum value of a thickness of the cathode from the upper face to the end face on the electron transport layer side is less than or equal to 1 μm.

9. The light-emitting device according to claim 1,
wherein, when a metal element is denoted by M and boron is denoted by B, the metal boride is MB₂ₙ (where, n is an integer).

10. The light-emitting device according to claim 9,
wherein the MB₂ₙ is any of LaB₆, LaB₁₀, LaB₁₂, and ZrB₂.

11. The light-emitting device according to claim 1,
wherein the light-emitting layer contains quantum dots.

12. The light-emitting device according to claim 1,
wherein a main component of the electron transport layer is zinc oxide.

13. The light-emitting device according to claim 1,
wherein a work function of the cathode is less than or equal to a work function of the electron transport layer.
